(19) United States
(12) Patent Application Publication
(10) Pub. No.: US 2011/0163384 A1
(43) Pub. Date: Jul. 7, 2011

(54) SEMICONDUCTOR DEVICE

(76) Inventor: Hiroaki Takasu, Chiba-shi (JP)

(21) Appl. No.: 12/984,148

(22) Filed: Jan. 4, 2011

(30) Foreign Application Priority Data
Jan. 6, 2010 (JP) 2010-001554

(51) Int. Cl. H01L 23/60

(52) U.S. Cl. 257/355; 257/E23.002

(57) ABSTRACT

Provided is a semiconductor device in which the drain region of the ESD protection NMOS transistor is electrically connected, through a drain extension region formed by an impurity diffusion region having the same conductivity as that of the drain region and arranged on both side surfaces and a bottom surface of the second trench isolation region which is formed next to the drain region, to the drain contact region formed by an impurity diffusion region having the same conductivity as that of the drain region.

### RELATED APPLICATIONS

This application claims priority under 35 U.S.C. §119 to Japanese Patent Application No. 2010-001554 filed on Jan. 6, 2010, the entire content of which is hereby incorporated by reference.

### BACKGROUND OF THE INVENTION

1. Field of the Invention

The present invention relates to a semiconductor device which includes, between an external connection terminal and an internal circuit region, an ESD protection element for protecting internal elements formed in the internal circuit region from breakdown triggered by ESD.

2. Description of the Related Art

In semiconductor devices having MOS transistors, it is a known practice to install an “off transistor” as an ESD protection element for preventing the breakdown of an internal circuit due to static electricity entering from an external connection terminal. The off transistor is an NMOS transistor which is kept in an off state by fixing its gate electric potential to a ground potential (Vss).

To prevent the ESD breakdown of an internal circuit element, it is important to draw as much part of ESD pulses as possible into the off transistor while inhibiting ESD pulses from propagating into the internal circuit element, or to convert a fast, large ESD pulse into a slow, small signal before propagation to inside.

The off transistor is often set to have a wide transistor width W in the order of several hundreds microns because, unlike other MOS transistors that constitute internal circuits such as a logic circuit, the off transistor needs to have an ability to pass a large amount of current caused by static electricity at once.

Accordingly the off transistor occupies a large area, which poses a problem particularly in a small-sized IC chip by increasing the overall cost of the IC.

An off transistor takes often a form of comb-shape in which a plurality of drain regions, source regions, and gate electrodes are combined to make a structure of a combination of a plurality of transistors, making it difficult to ensure a uniform operation in all parts of the ESD protection NMOS transistor, which would lead to a concentration of current in, for example, a place at a short distance from the external connection terminal and would cause a breakdown without giving the ESD protection NMOS transistor a chance to fully exert its intended ESD protection function.

An effective improvement for the problem is to set a long distance between a contact hole on a drain region and a gate electrode to pass current uniformly across the entire off transistor. Another improvement has been suggested in which the distance between a contact hole on a drain region and a gate electrode is made shorter as the distance from the external connection terminal increases in order to speed up the transistor operation (see JP 07-45829 A, for example).

However, reducing the width W in an attempt to reduce the occupation area of the off-transistor renders the off transistor incapable of implementing its protection function satisfactorily. The proposed improvement, in which the transistor operation speed is adjusted locally by adjusting the distance from a contact hole to the gate electrode in the drain region, also has additional problems including a failure to secure a desired distance between the contact hole and the gate electrode due to the reduced drain region width while a sufficient protection function is only maintained by keeping a long distance between the contact hole and the gate electrode, increasing the occupation area of the off transistor.

### SUMMARY OF THE INVENTION

To solve these problems, the present invention provides a semiconductor device having a following structure.

The semiconductor device according to the present invention includes: an internal element which is located in an internal circuit region; an ESD protection NMOS transistor provided between the internal circuit region and an external connection terminal in order to protect the internal element from breakdown caused by ESD; and trench isolation regions, in which a drain region of the ESD protection NMOS transistor is electrically connected, through a drain extension region formed by an impurity diffusion region having the same conductivity as that of the drain region and arranged on the side surfaces and the bottom surface of the trench isolation region, to a drain contact region formed by an impurity diffusion region having the same conductivity as that of the drain region.

In addition the drain region of the ESD protection NMOS transistor is electrically connected, through a drain extension region formed by an impurity diffusion region having the same conductivity as that of the drain region and arranged on the side surfaces and the bottom surfaces of a plurality of trench isolation regions, to a drain contact region formed by an impurity region having the same conductivity as that of the drain region.

In addition a source region of the ESD protection NMOS transistor is electrically connected, through a source extension region formed by an impurity diffusion region having the same conductivity as that of the source region and arranged on the side surfaces and the bottom surface of the trench isolation region, to a source contact region formed by an impurity diffusion region having the same conductivity as that of the source region.

With these measures, the distance between a contact hole on the drain region and the gate electrode or the distance between a contact hole on the source region and the gate electrode can be secured to be long, permitting a protection of local current concentration in the ESD protection NMOS transistor. A semiconductor device with an ESD protection NMOS transistor having a satisfactory ESD protection function can be thus provided.

### BRIEF DESCRIPTION OF THE DRAWINGS

In the accompanying drawings:

FIG. 1 is a schematic sectional view illustrating an ESD protection NMOS transistor according to the first embodiment of the present invention; and

FIG. 2 is a schematic sectional view illustrating an ESD protection NMOS transistor according to the second embodiment of the present invention

### DETAILED DESCRIPTION OF THE PREFERRED EMBODIMENTS

### 1. First Embodiment

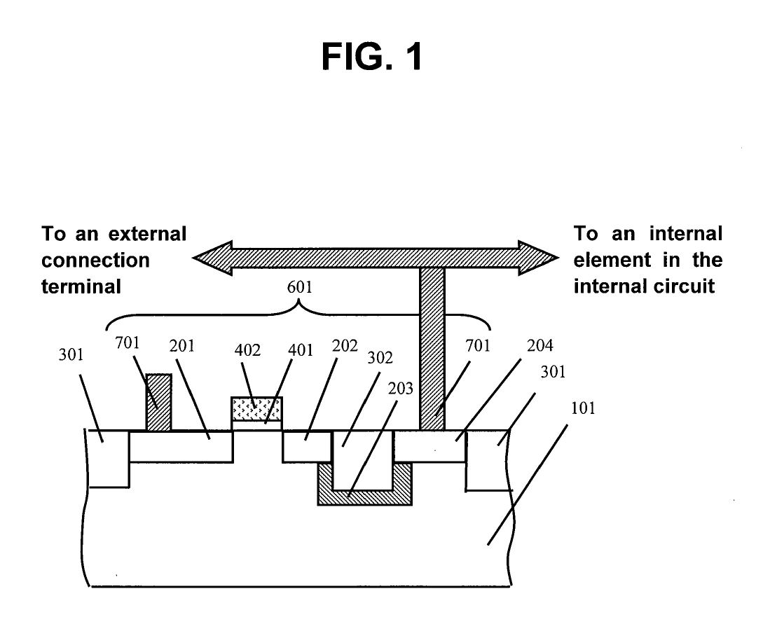

FIG. 1 is a schematic sectional view illustrating an ESD protection NMOS transistor in a semiconductor device according to the first embodiment of the present invention.

A pair of N-type high impurity concentration regions, a source region 201 and a drain region 202 of the ESD protection NMOS transistor, are formed on a P-type silicon substrate 101 which is a semiconductor substrate of the first conductivity and trench isolation regions 301, 302 are formed around the ESD protection NMOS transistor made by shallow trench isolation; the first trench isolation region 301 is formed to surround the whole ESD protection NMOS transistor for electrical isolation from other elements, the second trench isolation region 302 is formed between the drain region 202 and a drain contact region 204.

A gate electrode 402 made of polycrystalline silicon or the like is formed above a channel region in the P-type silicon substrate 101 between the source region 201 and the drain region 202 with a gate insulating film made of silicon oxide film or the like therebetween. In particular the drain region 202 is connected with a drain extension region 203, made of an impurity diffusion region having the same conductivity as that of the drain region 202 and arranged on the side surface and on the bottom surface of the second trench isolation region 302. Further the drain extension region 203 is connected with the drain contact region 204, made of an impurity diffusion region having the same conductivity as that of the drain region 202 and arranged on the other side of the second trench isolation region 302 to sandwich the second trench isolation region 302 with the drain region 202. A contact hole 701 filled by metal interconnect is formed on the drain contact region 204. An ESD protection NMOS transistor 601 according to the present invention is thus formed to have these features.

The resulting structure can provide a long distance between the gate-electrode-side edge of the drain 202 and the contact hole 701 within a smaller occupation area compared to a conventional planer arrangement of the drain, suppressing a local concentration of the current, which permits a realization of an ESD protection NMOS transistor having a uniform operation along the entire transistor width. Accordingly reduction of total occupation area for the protection transistors on an IC chip is possible, leading to a cost down.

### 2. Second Embodiment

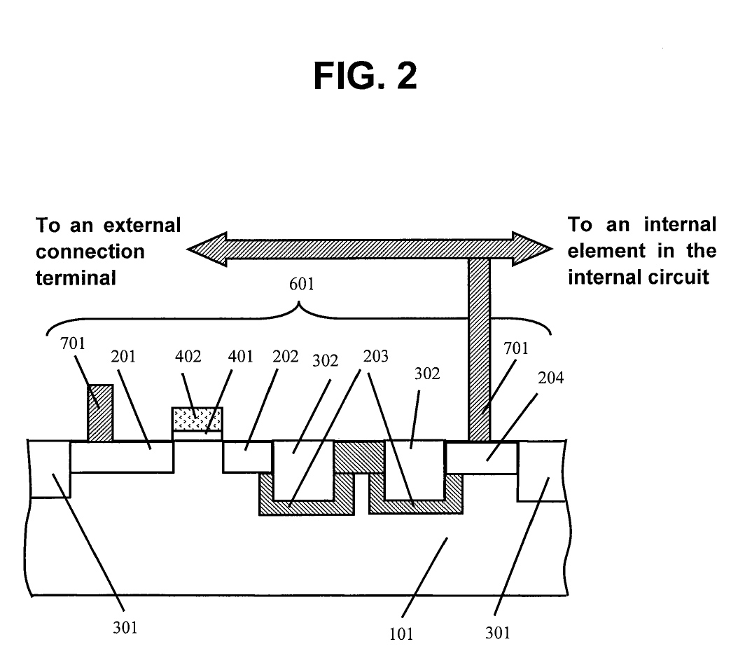

FIG. 2 is a schematic sectional view illustrating an ESD protection NMOS transistor in a semiconductor device according to the second embodiment of the present invention.

The difference from the first embodiment shown by FIG. 1 is that a drain extension region 203 connects a drain region 202 and a drain contact region 204 across two trench isolation regions 302.

When a longer distance between the gate-electrode-side edge of the drain 202 and the contact hole 701 is required, it is beneficial to connect the drain region 202 and the drain contact region 204 through a drain extension region across side surfaces and bottom surfaces of a plurality of trench isolation regions 302.

The second embodiment shown by FIG. 2 provides an example in which two trench isolation regions are used. Owing to the projected characteristics a longer distance can be set between the gate-electrode-side edge of the drain 202 and the contact hole 701 by the use of a plurality of trench isolation regions 302 while suppressing the increase in the occupation area.

In the first and the second embodiments the formation of the drain extension region 203 next to the drain region 202 of the ESD protection NMOS transistor 601 permits a longer distance between the gate-electrode-side edge of the drain 202 and the contact hole 701. Additional formation of a source extension region next to the source region 201, just as in the drain region 202, on the side surfaces and the bottom surfaces of the trench isolation region 301 permits a longer distance between the gate-electrode-side edge of the source 201 and the contact hole 701 of the source side.

The conductivity type of the drain extension region 203 is, of course, the same as that of the drain region 202. It would be good to balance the sheet resistance of the drain region 202 and the sheet resistance of the drain extension region 203 by adjusting the impurity concentration, thickness and width of the regions for better protection of unbalance, non-uniformity and concentration of the current.

By these measures large current can be passed uniformly through the ESD protection NMOS transistor without leaning to one side at the time of a bipolar action, permitting effective current passing caused by effective operation across the whole transistor channel width of the ESD protection NMOS transistor, even when a large amount of current or pulse is applied from outside.

Further in the present invention an effective drain region of the ESD protection NMOS transistor 601 can be regarded as a combination of the drain region 202, drain extension region 203, and drain contact region 204. When a large current in the forward direction is applied, the applied current should be passed away as a forward direction current through a junction diode formed by the N-type drain and the P-type substrate of the ESD protection NMOS transistor. Since the effective drain region of the ESD protection NMOS transistor is the combination of the drain region 202, drain extension region 203, and drain contact region 204 in the present invention, having a relatively large junction area in a relatively small occupation area, the large current can be passed away rapidly.

A semiconductor device having the ESD protection NMOS transistor 601 with a satisfactory ESD protection function is thus provided.

In the first and the second embodiments the ESD protection NMOS transistors having a conventional drain/source structure are shown for simplicity. The DDD structure or the offset drain structure can also be used in the same manner.

What is claimed is:

1. A semiconductor device, comprising:
an internal element located in an internal circuit region;
an ESD protection NMOS transistor provided between the internal circuit region and an external connection terminal in order to protect the internal element from breakdown caused by ESD, and having a drain region and a drain contact region;
a first trench isolation region arranged to surround the ESD protection NMOS transistor; and
a second trench isolation region arranged between the drain region and the drain contact region,
wherein the drain region of the ESD protection NMOS transistor is electrically connected, through a drain extension region formed by an impurity diffusion region having the same conductivity as that of the drain region and arranged on both side surfaces and a bottom surface of the second trench isolation region, to the drain contact region formed by an impurity diffusion region having the same conductivity as that of the drain region.

2. A semiconductor device, comprising:
an internal element located in an internal circuit region;
an ESD protection NMOS transistor provided between the internal circuit region and an external connection terminal in order to protect the internal element from breakdown caused by ESD, and having a drain region and a drain contact region;
a first trench isolation region formed to surround the ESD protection NMOS transistor; and
a plurality of second trench isolation regions formed between the drain region and the drain contact region,
wherein the drain region of the ESD protection NMOS transistor is electrically connected, through a drain extension region formed by an impurity diffusion region having the same conductivity as that of the drain region and arranged on both side surfaces and a bottom surface of each of the plurality of the second trench isolation regions, to the drain contact region formed by an impurity diffusion region having the same conductivity as that of the drain region.

3. The semiconductor device according to claim 1, further comprising:
a source region;
a source contact region; and
a third trench isolation region arranged between the source region and the source contact region,
wherein the source region is connected, through a source extension region formed by an impurity diffusion region having the same conductivity as that of the source region and arranged on both side surfaces and a bottom surface of the third trench isolation region, to a source contact region formed by an impurity diffusion region having the same conductivity as that of the source region.

4. The semiconductor device according to claim 1, wherein a sheet resistance of the drain extension region is the same as that of the drain region.
